(19) United States
(12) Patent Application Publication
(10) Pub. No.: US 2018/0001783 A1
(43) Pub. Date: Jan. 4, 2018

(54) METHOD FOR SETTING AN OPERATING PARAMETER OF BATTERIES

(71) Applicant: Dr. Ing. h.c. F. Porsche Aktiengesellschaft, Stuttgart (DE)

(72) Inventor: Dominik Schwichtenhoevel, Stuttgart (DE)

(21) Appl. No.: 15/632,401

(22) Filed: Jun. 26, 2017

(30) Foreign Application Priority Data
Jul. 4, 2016 (DE) 10 2016 112 173.8

(51) Int. Cl. B60L 11/18; B60L 11/14; H01M 10/44; B60L 3/00; G01R 31/36; H01M 10/48

(52) U.S. Cl. CPC B60L 11/1862; G01R 31/3648; H01M 10/48; H01M 10/44; B60L 3/0046; G01R 31/3606; B60L 11/14; Y02T 10/7005

(57) ABSTRACT

A method for setting at least one aging-influencing operating parameter of batteries for motor vehicles includes assigning batteries to a fleet of batteries; recording at least one characteristic variable for an aging state of batteries of at least one selection of batteries from the fleet of batteries; determining at least one aging state of the at least one selection of batteries or the fleet of batteries on the basis of the at least one characteristic variable recorded in the case of the selection of batteries; and setting the at least one operating parameter in dependence on the determined aging state of the at least one selection of batteries or the fleet of batteries for controlling the aging state in the case of at least one battery to be controlled of the at least one selection of batteries, a further selection of batteries, or the fleet of batteries.

### CROSS REFERENCE TO RELATED APPLICATIONS

This application claims benefit to German Patent Application No. DE 10 2016 112 173.8, filed Jul. 4, 2016, which is hereby incorporated by reference herein.

### FIELD

The present invention relates to a method for setting at least one aging-influencing operating parameter of batteries for motor vehicles.

### BACKGROUND

In electric vehicles and hybrid vehicles, the electrical propulsive drive is generally supplied by an energy store in the form of a battery. Such batteries usually account for a significant proportion of overall costs of the vehicle. Therefore, along with the performance, the lifetime of the battery is also an important feature of an electric or hybrid vehicle.

However, batteries are subject to a time- and use-dependent aging process. The monitoring and control of the aging process is therefore a particularly important aspect for the lifetime of batteries in motor vehicles.

In the prior art, it is proposed, for example, to measure a battery with regard to its aging state and to compare the measured aging state with a desired state. If the comparison shows for example that the measured aging is greater than the desired aging, an adaptation of the operating parameters is proposed. In this case, for example, the energy swings during charging and discharging are reduced in order to slow down the aging rate.

A disadvantage of this however is that the adaptation of the operating parameters only takes place when an increased degradation of the battery has already been measured. Thus, although the future aging process can be influenced by the adaptation of the operating parameters, the effects of the previous aging must be accepted.

### SUMMARY

In an embodiment, the present invention provides a method for setting at least one aging-influencing operating parameter of batteries for motor vehicles. The method includes assigning batteries to a fleet of batteries; recording at least one characteristic variable for an aging state of batteries of at least one selection of batteries from the fleet of batteries; determining at least one aging state of the at least one selection of batteries or the fleet of batteries on the basis of the recorded at least one characteristic variable, and setting the at least one operating parameter in dependence on the determined aging state of the at least one selection of batteries or the fleet of batteries for controlling the aging state in the case of at least one battery to be controlled of the at least one selection of batteries, a further selection of batteries, or the fleet of batteries.

### BRIEF DESCRIPTION OF THE DRAWINGS

The present invention will be described in even greater detail below based on the exemplary figures. The invention is not limited to the exemplary embodiments. All features described and/or illustrated herein can be used alone or combined in different combinations in embodiments of the invention. The features and advantages of various embodiments of the present invention will become apparent by reading the following detailed description with reference to the attached drawings which illustrate the following:

FIG. 1 shows a highly schematized diagram of a monitoring system for carrying out a method according to an embodiment of the invention; and

FIG. 2 shows a further diagram of the monitoring system.

### DETAILED DESCRIPTION

A method is described herein for setting at least one aging-influencing operating parameter of batteries for motor vehicles. The method offers improved setting of aging-influencing operating parameters.

Methods according to embodiments of the invention operate to set at least one aging-influencing operating parameter of batteries for motor vehicles and, in particular, of traction batteries for hybrid vehicles and/or electric vehicles. According to embodiments, the batteries are assigned to at least one fleet of batteries. At least one characteristic variable for an aging state of, in particular, individual batteries of at least one selection of batteries from the fleet of batteries, is recorded. On the basis of the characteristic variable recorded from the selection of batteries, a determination of at least one aging state of the at least one selection of batteries or the fleet of batteries is performed. In dependence on the determined aging state of the at least one selection of batteries or the fleet of batteries, the setting of the at least one operating parameter is performed. The setting of the operating parameter is used for controlling the aging state in the case of at least one battery of the fleet of batteries.

Methods according to embodiments of the invention may have many advantages. One considerable advantage is that the control of the aging state of one or more batteries takes place with allowance for the determined aging state of the at least one selection of batteries or the fleet of batteries. This offers an advantageous setting of the operating parameters that can preventively influence the aging. The control on the basis of the aging state of the at least one selection of batteries or the fleet of batteries makes it possible, for example, to influence the aging behavior of the batteries already before any degradation or clearly evident degradation has occurred. Methods according to embodiments of the invention consequently offer a particularly favorable way of influencing the lifetime of a battery.

The battery is in particular in the form of an electrical energy store for electric vehicles and/or hybrid vehicles and preferably a high-voltage battery. The battery is preferably in the form of a traction battery. The battery preferably comprises a multiplicity of battery cells which are combined in groups to form a plurality of battery modules.

Within the scope of the present invention, the term aging state can be understood to mean a State of Health (SOH) of the batteries. The recorded characteristic variable is in particular a characteristic variable for the State of Health of the batteries. Particularly preferably, a recording of at least two and preferably a plurality of characteristic variables for the aging state is performed. The characteristic variable for the aging state may for example describe an internal resistance and/or a capacity of the respective battery.

The setting of the battery parameter is preferably performed independently of whether or not the battery to be controlled belongs to the selection of batteries. As a result, the aging state can be preventively influenced particularly well. Thus, all batteries of the fleet of batteries can benefit from the setting, without this requiring each individual battery of the fleet of batteries first to be investigated.

It is possible that, at the time of the setting of the operating parameter, the battery to be controlled does not belong to the selection of batteries. In particular, the battery may be added to the selection of batteries at a later time. It is also possible that the battery to be controlled already belongs to the selection of batteries at the time of the setting of the operating parameter.

The selection of batteries is preferably increased over time. In particular, the number of batteries of the selection of batteries increases with time. For example, each time a motor vehicle is taken to a workshop, its battery can be registered and added to the selection of batteries. It is also possible that batteries are removed from the selection of batteries. The selection of batteries is preferably changed dynamically over time.

Particularly preferably, the setting of the operating parameter is performed both in the case of the batteries of the selection of batteries and in the case of at least some of the remaining batteries of the fleet of batteries. Particularly preferably, the setting of the operating parameter is performed in the case of all the batteries of the fleet of batteries. In this case, the setting of the operating parameter may be performed at different times in the case of the respective batteries of the fleet of batteries.

The setting of the operating parameter is preferably performed in such a way that a closed-loop control of the aging state of the at least one selection of batteries, a further selection of batteries or the fleet of batteries to a desired aging state takes place. This is of advantage in particular whenever the aging state of the at least one selection of batteries or the fleet of batteries deviates from the desired aging state, and consequently indicates an increased degradation of the batteries under certain settings of the operating parameter. In particular, the control of the aging state of the at least one selection of batteries, a further selection of batteries or the fleet of batteries to the desired aging state takes place independently of whether or not the battery to be controlled belongs to the selection of batteries. This has the advantage that a battery can be controlled to the desired aging state without previously having to be investigated.

The control to the desired aging state takes place in particular independently of an actual aging state in reality of the battery to be controlled. Thus, the actual aging state in reality does not have to be determined before it is possible to control to the desired aging state. Used in particular instead of the actual aging state of the battery is the aging state of the at least one selection of batteries or the fleet of batteries, which advantageously allows for the findings concerning a great number of batteries of the fleet.

This is particularly advantageous in the case of batteries which at the time of the recording or control do not yet have any evident changes of the characteristic variable for the aging state. With a conventional closed-loop control, no control would be performed in the case of such batteries because of the still positive actual state. By contrast, the closed-loop control presented here, with allowance for the aging state of the at least one selection of batteries or the fleet of batteries, makes possible an improvement of the future aging on the basis of the findings from the overall fleet. Aging problems that have not yet occurred can be reliably counteracted already in advance.

In various embodiments, it is possible that the desired aging state is dynamically adapted with allowance for the recorded characteristic variable. It is also preferred that the desired aging state is dynamically adapted with allowance for the aging state of the at least one selection of batteries or the fleet of batteries. Thus, the desired aging state can be redefined when the evaluation of the recorded characteristic variable indicates that a closed-loop control to the previous desired value does not lead to optimum aging. The desired aging state can also be adapted when further batteries are added to the selection of batteries and evaluated, and the aging state of the at least one selection of batteries or the fleet of batteries consequently changes on the basis of new findings. Instead of or in addition to a dynamically adapted desired aging state, a predefined desired aging state may also be used.

It is also possible that the desired aging state is adapted individually for individual batteries of the fleet of batteries. For example, an adaptation of the desired aging state of an individual battery may be performed on the basis of its actual aging state in reality.

Particularly preferably, an operating setting of the at least one aging-influencing operating parameter is also recorded along with the characteristic variable in the case of the batteries of the selection of batteries. The operating setting of the operating parameter describes in particular at least one value to which the operating parameter has been set. The operating setting may also describe a variation over time of the values to which the operating parameter has been set over a defined period of time. The operating setting may also define whether an operating parameter is deactivated or active. The operating setting may also define whether or not an operating parameter can be set in the case of a battery. For example, batteries of the selection of batteries may differ in their functions, so that the operating setting provides information on whether or not there is a function concerning a certain operating parameter.

Preferably, at least one assignment parameter is determined on the basis of the recorded characteristic variable and the recorded operating setting. The assignment parameter describes in particular at least one relationship between the operating setting of the aging-influencing operating parameter and the aging state of the at least one selection of batteries or the fleet of batteries. The assignment parameter may also describe at least one relationship between the operating setting of the operating parameter and the actual aging state in reality of an individual battery of the fleet of batteries.

Preferably, at least one operating setting that leads to an unfavorable aging of the batteries of the fleet of batteries is determined on the basis of the assignment parameter. Particularly preferably, those operating parameters that exert a significant influence on the aging may also be detected on the basis of the assignment parameter. As a result, very useful information about which operating parameters in specific types of battery lead to an unfavorable or increased aging can be obtained on the basis of the evaluation of the batteries. In particular, a plurality of operating parameters are monitored and used for determining the assignment parameter. Then, those operating parameters that influence the aging more strongly than other operating parameters can be set with priority in the control of the aging state.

Preferably, the setting of the operating parameter for controlling the aging state of the at least one selection of batteries, a further selection of batteries or the fleet of batteries is also performed with allowance for the assignment parameter. Since particularly critical operating parameters or unfavorable settings of the operating parameter are identifiable on the basis of the assignment parameter, settings that lead to an unfavorable aging can thus be avoided. As a result, the lifetime of the batteries can be influenced particularly advantageously.

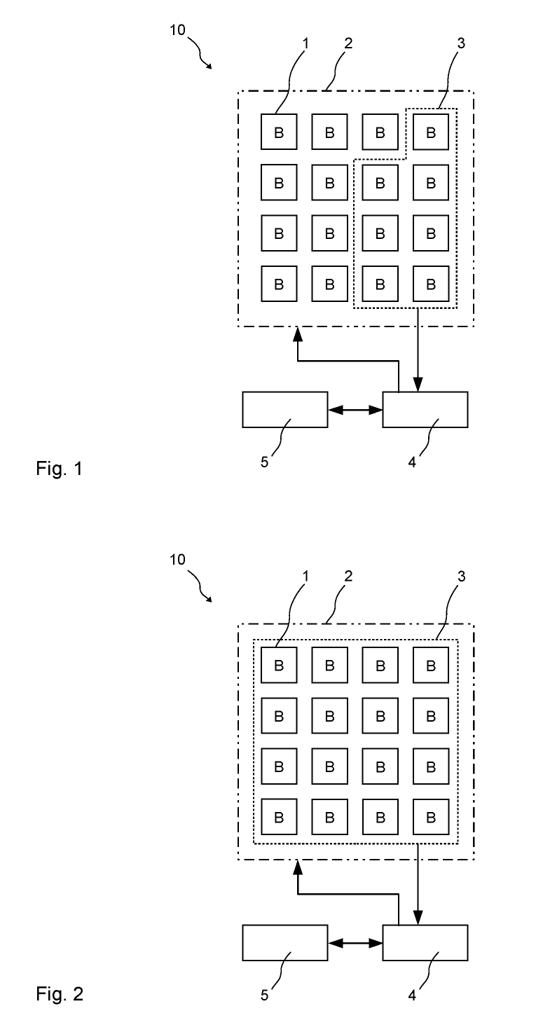

FIG. 1 shows a monitoring system 10 for carrying out the method according to the invention. The monitoring system 10 comprises a multiplicity of batteries 1, which are assigned to a fleet of batteries 2. The monitoring system 10 also comprises a selection of batteries 3, a server 4 and an evaluation device 5.

Here, the batteries 1 are fitted as traction batteries in electric vehicles and/or hybrid vehicles. For better overall clarity, the vehicles are not represented. The vehicles preferably comprise a propulsive drive, which is supplied with electrical energy by the respective battery 1. The batteries 1 in each case comprise in particular power electronics and a control device for performing operating settings for operating parameters.

The assignment of batteries 1 to a fleet of batteries 2 is performed, for example, on the basis of the type and/or the design and/or the series of the batteries. The assignment may also be performed on the basis of the operating conditions under which the batteries 1 are operated. The assignment may also be performed on the basis of the type of motor vehicles in which the batteries 1 are fitted.

The number of batteries 1 shown here of the fleet of batteries 2 serves in particular for purposes of illustration. Preferably, the fleet of batteries 2 comprises a much greater number of batteries 1. A fleet of batteries 2 may for example comprise several hundred or even several thousand batteries 1. However, smaller or larger fleets of batteries 2 are also possible.

The monitoring system 10 serves here for setting at least one aging-influencing operating parameter of the batteries 1.

The monitoring system 10 is used to record at least one characteristic variable for an aging state in the case of the selection of batteries 3 from the fleet of batteries 2. In this case, the number of batteries 1 of the selection of batteries 3 is fixed in particular such that the selection of batteries 3 is representative of the fleet of batteries 2. Alternatively, the selection of batteries 3 may also represent a subset of the fleet of batteries 2 that is distinguished for example by different environmental or driving conditions. Thus, the selection of batteries 3 may for example represent that subset of the fleet of batteries 2 that is operated in cold countries, i.e. countries with average annual temperatures below a defined temperature. Preferably, the characteristic variable for the aging state is recorded in the case of as many batteries 1 as possible or all the batteries 1 of the selection of batteries 3, in order to obtain representative information about the aging state. However, it is also possible at the expense of the accuracy of the information about the aging state to record only the characteristic variable for the aging state of individual batteries 1 of the selection of batteries 3. Moreover, the characteristic variable for the aging state that is recorded from batteries 1 of the selection of batteries 3 may be used for controlling the aging state in the case of at least one battery 1 of a further selection of batteries from the fleet of batteries 2.

In FIG. 1, only some of the batteries 1 of the fleet of batteries 2 have been added to the selection of batteries 3. This may be the case whenever not all the batteries 1 of the fleet of batteries 2 have been subjected as yet to recording of the characteristic variable for the aging state. This occurs for example whenever only some of the batteries 1 have so far been taken to a workshop or not all the batteries 1 have set up a corresponding connection with the server 4.

FIG. 2 shows the monitoring system 10 of FIG. 1 with an increased selection of batteries 3. Here, all the batteries 1 of the fleet of batteries 2 have been added to the selection of batteries 3. The size of the selection of batteries 3 may vary for example as a result of new additions or as a result of removals from the selection of batteries 3.

The characteristic variable for the aging state of the batteries 1 may for example describe an internal resistance or the capacity of the respective battery 1. The recording of the characteristic variable is then performed for example by the determination of the internal resistance or the capacity. Other and preferably further characteristic variables for the aging state may also be recorded, so that information that is as detailed as possible about the aging state or State of Health can be obtained.

Here, the recorded characteristic variables are stored on a central server 4. The transmission of the data to the server 4 may take place for example by way of a mobile and/or stationary data transmission. The data may also be recorded by being read out when the vehicle or battery is taken to a workshop and be transmitted from there to a central server 4. The data stored on the server 4 are preferably retrieved and evaluated by way of an evaluation device 5. The evaluation device can include, for example, one or more processors or processor cores having stored thereon processor executable instructions.

On the basis of the recorded characteristic variables, an aging state of the selection of batteries 3 or the fleet of batteries 2 is then determined, e.g., by way of the evaluation device 5. The aging state of the selection of batteries 3 or the fleet of batteries 2 is determined, for example, on the basis of the values of the characteristic variable recorded in the case of the individual batteries 1. If the recorded characteristic variable is for example the internal resistance, a parameter that defines statistical information about the internal resistance of all the batteries 1 of the selection of batteries 3 or the fleet of batteries 2 may be calculated (e.g. by the evaluation device 5) as the aging state of the selection of batteries 3 or the fleet of batteries 2. Thus, reliable information about the aging state of the batteries 1 of the entire fleet of batteries 2 can be determined on the basis of the investigation of the selection of batteries 3.

A setting of the operating parameter is performed with allowance for the determined aging state of the selection of batteries 3 or the fleet of batteries 2 in the case of the batteries 1 of the fleet of batteries 2. In particular, the batteries 1 are controlled to a desired aging state on the basis of the aging state of the selection of batteries 3 or the fleet of batteries 2. In this case, the batteries 1 that do not belong to the selection of batteries 3 are also controlled. Moreover, it may be provided that there is no allowance for the aging state in reality of the respective battery 1 in the control to the desired aging state.

If for example the aging state of the selection of batteries 3 or the fleet of batteries 2 reveals an increased degradation of the fleet of batteries 2 in comparison with the desired aging state, a closed-loop control of the operating parameters may also be performed in the case of the batteries 1 in which no degradation has so far been established. Consequently, the control of the aging state of the selection of batteries 3 or the fleet of batteries 2 to the desired aging state offers the possibility of having a preventive influence.

The aging-influencing operating parameters may for example concern the energy swings during charging operations and/or discharging operations of the battery 1. The setting to smaller or greater energy swings allows the aging state of the battery 1 to be controlled correspondingly, since the aging rate is influenced considerably by the intensity of the energy swings. The aging-influencing operating parameters may for example also be the state of charge and/or the peak power and/or the continuous power, the reliable voltage for the discharging or for the charging and/or thermal operating settings, such as for example the temperature of the vehicle during parking.

The evaluation of the recorded characteristic variables and/or the calculation of the aging state of the selection of batteries 3 or the fleet of batteries 2 and also the specifications for the control of the aging state are preferably performed by the evaluation device 5. In this case, the evaluation device 5 may be in connection with the respective batteries 1 by way of a mobile and/or stationary data transmission connection. The control devices of the respective battery 1 then allow for the specifications of the evaluation device 5.

In addition to the characteristic variable for the aging state, preferably the corresponding operating settings of the aging-influencing operating parameters of the battery 1 are also recorded. An assignment parameter is preferably calculated from the recorded characteristic variable and the associated operating setting for the operating parameter. This assignment parameter describes the relationship between the operating setting and the aging state of the batteries 1 of the selection of batteries 3 or the fleet of batteries 2. This offers the possibility of identifying those operating parameters that have a particularly characteristic influence on the aging of the battery 1. Moreover, operating settings in the case of which the operating parameters are set to values that influence the aging particularly disadvantageously can be avoided. The allowance for the assignment parameter in the control allows particularly decisive operating settings with regard to the aging to be optimally set or controlled.

The method presented here uses the monitoring of the aging state of the batteries 1 of an entire fleet of batteries 2 for setting operating parameters of each individual battery 1 optimally on this basis. This approach offers the possibility of using the fleet of batteries 2 to obtain reliable information about which operating parameters in a specific type of battery lead to increased aging. Moreover, the setting of the operating parameters can be corrected in accordance with an aging state of the selection of batteries 3 or the fleet of batteries 2.

The allowance for the aging state of the selection of batteries 3 or the entire fleet of batteries 2 also allows the operating parameters in the case of not yet aged batteries 1 to be adjusted to the suitable values for advantageously influencing the aging. This makes preventive control of the operating parameters possible. Moreover, preventive control can be performed without it being absolutely necessary to carry out a measurement on the battery 1 that is actually concerned.

While the invention has been illustrated and described in detail in the drawings and foregoing description, such illustration and description are to be considered illustrative or exemplary and not restrictive. It will be understood that changes and modifications may be made by those of ordinary skill within the scope of the following claims. In particular, the present invention covers further embodiments with any combination of features from different embodiments described above and below.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE NUMERALS

1 battery
2 fleet of batteries
3 selection of batteries
4 server
5 evaluation device
10 monitoring system

What is claimed is:

1. A method for setting at least one aging-influencing operating parameter of batteries for motor vehicles, the method comprising:
assigning batteries to a fleet of batteries;
recording at least one characteristic variable for an aging state of batteries of at least one selection of batteries from the fleet of batteries;
determining at least one aging state of the at least one selection of batteries or the fleet of batteries on the basis of the recorded at least one characteristic variable; and
setting the at least one operating parameter in dependence on the determined aging state of the at least one selection of batteries or the fleet of batteries for controlling the aging state in the case of at least one battery to be controlled of the at least one selection of batteries, a further selection of batteries, or the fleet of batteries.

2. The method as claimed in claim 1, wherein the setting of the at least one operating parameter is performed independently of whether or not the battery to be controlled belongs to the selection of batteries.

3. The method as claimed in claim 1, wherein the setting of the at least one operating parameter is performed both in the case of the batteries of the selection of batteries and in the case of at least some of the remaining batteries of the fleet of batteries.

4. The method as claimed in claim 1, further comprising setting at least one operating parameter for controlling the aging state of a further selection of batteries or the fleet of batteries to a desired aging state.

5. The method as claimed in claim 4, wherein the setting at least one operating parameter for controlling the aging state of a further selection of batteries or the fleet of batteries to the desired aging state takes place independently of an actual aging state in reality of the battery to be controlled.

6. The method as claimed in claim 4, wherein the desired aging state is dynamically adapted with allowance for the recorded characteristic variable and/or the aging state of the at least one selection of batteries or the fleet of batteries.

7. The method as claimed in claim 1, wherein an operating setting of the at least one aging-influencing operating parameter is recorded along with the characteristic variable in the case of the batteries of the selection of batteries.

8. The method as claimed in claim 7, further comprising determining, on the basis of the recorded characteristic variable and the recorded operating setting, at least one assignment parameter that describes at least one relationship between the operating setting of the aging-influencing operating parameter and the aging state of the at least one selection of batteries, the fleet of batteries, and/or the actual aging state in reality of an individual battery so as to identify operating settings that lead to an unfavorable aging on the basis of the assignment parameter.

9. The method as claimed in claim 8, wherein the setting of the operating parameter for controlling the aging state of the at least one selection of batteries, a further selection of batteries, or the fleet of batteries is performed with allowance for the assignment parameter to avoid operating settings that lead to an unfavorable aging.
